(19) United States
(12) Patent Application Publication
(10) Pub. No.: US 2025/0054825 A1
(43) Pub. Date: Feb. 13, 2025

(54) SEMICONDUCTOR PACKAGE AND SEMICONDUCTOR ASSEMBLY INCLUDING THE SAME

(71) Applicant: SAMSUNG ELECTRONICS CO., LTD., Suwon-si (KR)

(72) Inventors: Jaehyun LIM, Suwon-si (KR); Youngjun Yoon, Suwon-si (KR); Yechung Chung, Suwon-si (KR); Inho Choi, Suwon-si (KR)

(73) Assignee: SAMSUNG ELECTRONICS CO., LTD., Suwon-si (KR)

(21) Appl. No.: 18/427,051

(22) Filed: Jan. 30, 2024

(30) Foreign Application Priority Data
Aug. 11, 2023 (KR) 10-2023-0105625

(51) Int. Cl. H01L 23/31; H01L 23/00; H01L 23/498; H01L 23/64; H01L 25/18

(52) U.S. Cl. CPC H01L 23/3121; H01L 23/49811; H01L 23/642; H01L 23/645; H01L 23/647; H01L 25/18; H01L 24/16; H01L 2224/16227

(57) ABSTRACT

An embodiment provides a semiconductor package including: a substrate having a first surface and a second surface disposed in an opposite direction to the first surface; a semiconductor chip disposed on at least one surface of the substrate; an electronic device disposed on the second surface of the substrate; a first molding layer disposed on the first surface of the substrate; and a second molding layer disposed on the second surface of the substrate, wherein the second molding layer has an open hole that exposes at least a portion of the electronic device to the outside, and a material of the second molding layer is located on an inner surface of the open hole.

### CROSS-REFERENCE TO RELATED APPLICATION

This application claims priority to and the benefit of Korean Patent Application No. 10-2023-0105625 filed in the Korean Intellectual Property Office on Aug. 11, 2023, the entire contents of which are incorporated herein by reference.

### BACKGROUND

### 1. Field

The present disclosure relates to a semiconductor package and a semiconductor assembly including the same.

### 2. Description of Related Art

Generally, a packaging process is performed on semiconductor chips formed by performing various semiconductor processes on a wafer to form a semiconductor package. The semiconductor package may include a semiconductor chip, a semiconductor package substrate on which the semiconductor chip is mounted, a chip connection bump that electrically connects the semiconductor chip and the semiconductor package substrate, and a protective insulating layer in contact with the chip connection bumps. Along with higher integration of semiconductor packages, improvements in reliability and processability of semiconductor packages are required.

### SUMMARY

The disclosure provides a semiconductor package including a plurality of semiconductor chips and electronic devices in a smaller size, and a semiconductor assembly including the same.

According to an aspect of the disclosure, a semiconductor package includes: a substrate including a first surface and a second surface, wherein the second surface is disposed in an opposite direction to the first surface; a semiconductor chip on one of the first surface or the second surface; a first electronic device on the second surface; a first molding layer on the first surface; and a second molding layer on the second surface, wherein the second molding layer comprises an first open hole that exposes at least a portion of the first electronic device to an outside, and wherein a material of the second molding layer is located on at least a portion of an inner surface of the first open hole.

According to an aspect of the disclosure, a semiconductor package includes: a substrate comprising a first surface and a second surface, wherein the second surface is disposed in an opposite direction to the first surface; a first semiconductor chip on the first surface; a second semiconductor chip on the second surface; a first electronic device on the first surface; a second electronic device on the second surface; a first molding layer on the first surface; and a second molding layer on the second surface, wherein the second molding layer comprises a first open hole that exposes at least a portion of the second electronic device to an outside, wherein a material of the second molding layer is located on at least a portion of an inner surface of the first open hole, and wherein a connection terminal connected to an external electrode of the second electronic device is disposed inside the first open hole.

According to an aspect of the disclosure, a semiconductor assembly includes: a main substrate; and a semiconductor package mounted on the main substrate, wherein the semiconductor package comprises: a substrate comprising a first surface and a second surface, wherein the second surface is disposed in an opposite direction to the first surface; a first semiconductor chip on the first surface; a second semiconductor chip on the second surface; a first electronic device on the first surface; a second electronic device on the second surface; a first molding layer on the first surface; and a second molding layer on the second surface, wherein the second molding layer comprises an open hole that exposes at least a portion of the second electronic device to an outside, wherein a material of the second molding layer is located on at least a portion of an inner surface of the open hole, and wherein a connection terminal connected to an external electrode of the second electronic device is disposed inside the open hole.

According to an aspect of the disclosure, a semiconductor package includes: a substrate comprising a first surface and a second surface, wherein the second surface is disposed in an opposite direction to the first surface; a semiconductor chip on one of the first surface or the second surface; an electronic device on the second surface, the electronic device comprising: a body; a first external electrode disposed on an outer surface of the body; and a second external electrode disposed on the outer surface of the body; and a molding layer on the second surface, wherein the molding layer comprises an open hole that exposes at least a portion of the electronic device to an outside, and wherein the open hole is disposed in an area of the molding layer corresponding to a position of the electronic device.

According to one or more embodiments, it is possible to provide a semiconductor package including a plurality of semiconductor chips and electronic devices in a smaller size, and a semiconductor assembly including the same.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates a cross-sectional view of a semiconductor package according to an embodiment;

FIG. 2 illustrates an enlarged view of a portion of the semiconductor package of FIG. 1;

FIGS. 3, 4 and 5 illustrate a process in which a connection terminal is connected to an external electrode of a second electronic device;

FIG. 6 illustrates a lower surface of a semiconductor package according to a first embodiment;

FIG. 7 illustrates a lower surface of a semiconductor package according to a second embodiment;

FIG. 8 illustrates a lower surface of a semiconductor package according to a third embodiment;

FIG. 9 illustrates a lower surface of a semiconductor package according to a fourth embodiment;

FIG. 10 and FIG. 11 illustrate a state in which a connection terminal is connected to a second electronic device according to the second embodiment;

FIG. 12 and FIG. 13 illustrate a state in which a connection terminal is connected to a second electronic device according to the third embodiment; and

FIG. 14 illustrates a semiconductor assembly including a semiconductor package according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each constituent element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Herein, the expression “at least one of a, b or c” indicates “only a,” “only b,” “only c,” “both a and b,” “both a and c,” “both b and c,” or “all of a, b, and c.”

It will be understood that, although the terms first, second, third, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

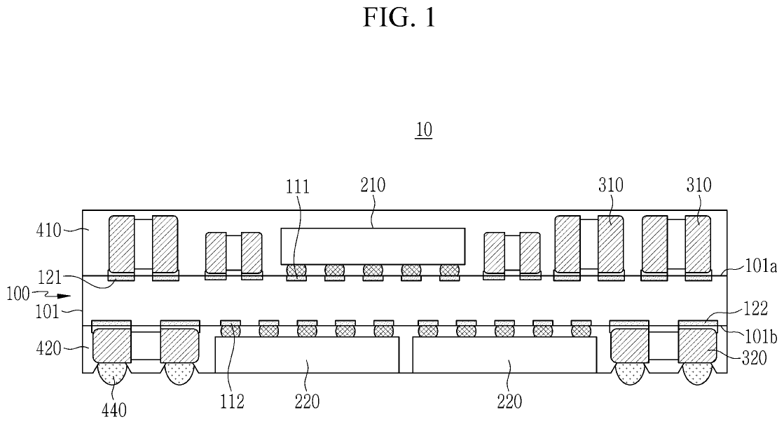

FIG. 1 illustrates a cross-sectional view of a semiconductor package according to an embodiment.

Referring to FIG. 1, a semiconductor package 10 according to an embodiment includes a substrate 100, semiconductor chips 210 and 220, electronic devices 310 and 320, and molding layers 410 and 420.

The substrate 100 may connect the semiconductor chips 210 and 220 to the outside. The substrate 100 may be a printed circuit board, a redistribution substrate, or the like. The substrate 100 includes a first surface and a second surface disposed to face in opposite directions. FIG. 1 shows a case in which the first surface of the substrate 100 faces upward and the second surface of the substrate 100 faces downward.

Hereinafter, the first surface of the substrate 100 is referred to as an upper surface of the substrate 100, and the second surface of the substrate 100 is referred to as a lower surface of the substrate 100. In addition, a direction in which the upper and lower surfaces are spaced apart from each other is referred to as a vertical direction.

The substrate 100 includes a substrate body 101, chip pads 111 and 112, and device pads 121 and 122.

The substrate body 101 may include an insulating material. The insulating material may be a thermosetting resin such as an epoxy resin, or a thermoplastic resin such as a polyimide. In addition, the insulating material may be impregnated with a reinforcing material such as glass fiber or inorganic filler. For example, the insulating material may be prepreg, Ajinomoto build-up film (ABF), FR-4, Bismaleimide Triazine (BT) resin, or the like. A wire structure and the like may be disposed in an inner area of the substrate body 101. The substrate body 101 may have a first surface 101a and a second surface 101b disposed to face in opposite directions.

A passivation layer may be disposed on the first surface 101a and the second surface 101b of the substrate body 101. The passivation layer may be formed through a solder resist or the like.

Corresponding to the substrate 100, the first surface 101a of the substrate body 101 may be an upper surface of the substrate body 101, and the second surface 101b of the substrate body 101 may be a lower surface of the substrate body 101.

The chip pads 111 and 112 are disposed in an area in a direction of the first surface 101a of the substrate body 101 or an area in a direction of the second surface 101b thereof. The chip pads 111 and 112 may be exposed to an exterior of the substrate 100.

The chip pads 111 and 112 may include a first chip pad 111 and a second chip pad 112.

The first chip pad 111 may be disposed in an area in a direction of the first surface 101a of the substrate body 101. The first chip pad 111 may be disposed on the first surface of the substrate 100 to be exposed to an exterior of the substrate 100. A plurality of first chip pads 111 may be provided. The plurality of first chip pads 111 may be arranged in a lattice structure. The first chip pad 111 may be understood as the upper chip pad 111. The first chip pad 111 may be made of a conductive material. The first chip pad 111 may be made of a metallic material. For example, the first chip pad 111 may be made of copper (Cu), silver (Ag), palladium (Pd), aluminum (Al), nickel (Ni), titanium (Ti), gold (Au), platinum (Pt), or an alloy thereof.

The second chip pad 112 may be disposed in an area in a direction of the second surface 101b of the substrate body 101. The second chip pad 112 may be disposed on the second surface of the substrate 100 to be exposed to an exterior of the substrate 100. A plurality of second chip pads 112 may be provided. The plurality of second chip pads 112 may be arranged in a lattice structure. The second chip pad 112 may be understood as the lower chip pad 112. The second chip pad 112 may be made of a conductive material. The second chip pad 112 may be made of a metallic material. For example, the second chip pad 112 may be made of copper (Cu), silver (Ag), palladium (Pd), aluminum (AI), nickel (Ni), titanium (Ti), gold (Au), platinum (Pt), or an alloy thereof.

The device pads 121 and 122 are disposed in an area in a direction of the first surface 101a of the substrate body 101 or an area in a direction of the second surface 101b thereof. The device pads 121 and 122 may be exposed to an exterior of the substrate 100.

The device pads 121 and 122 may include a first device pad 121 and a second device pad 122.

The first device pad 121 may be disposed in an area in a direction of the first surface 101a of the substrate body 101. The first device pad 121 may be disposed on the first surface of the substrate 100 to be exposed to an exterior of the substrate 100. A plurality of first device pads 121 may be provided. The first device pad 121 may be understood as the upper device pad 121. The first device pad 121 may be made of a conductive material. The first device pad 121 may be made of a metallic material. For example, the first device pad 121 may be made of copper (Cu), silver (Ag), palladium (Pd), aluminum (AI), nickel (Ni), titanium (Ti), gold (Au), platinum (Pt), or an alloy thereof.

The second device pad 122 may be disposed in an area in a direction of the second surface 101b of the substrate body 101. The second device pad 122 may be disposed on the second surface of the substrate 100 to be exposed to an exterior of the substrate 100. A plurality of second device pads 122 may be provided. The second device pad 122 may be understood as the lower device pad 122. The second device pad 122 may be made of a conductive material. The second device pad 122 may be made of a metallic material. For example, the second device pad 122 may be made of copper (Cu), silver (Ag), palladium (Pd), aluminum (Al), nickel (Ni), titanium (Ti), gold (Au), platinum (Pt), or an alloy thereof.

The semiconductor chips 210 and 220 are disposed on at least one surface of the substrate 100. The semiconductor chips 210 and 220 may include a first semiconductor chip 210 and a second semiconductor chip 220.

The first semiconductor chip 210 may be disposed on the first surface of the substrate 100. The first semiconductor chip 210 may be understood as the upper semiconductor chip 210. The first semiconductor chip 210 may be a logic semiconductor chip, a system on chip, and the like. The first semiconductor chip 210 may be connected to the first chip pad 111. A chip terminal may be disposed on a surface of the first semiconductor chip 210 facing the substrate 100, and the chip terminal may be connected to the first chip pad 111. The chip terminal may be a solder bump, a solder ball, or the like.

The second semiconductor chip 220 may be disposed on the second surface of the substrate 100. The second semiconductor chip 220 may be understood as the lower semiconductor chip 220. The second semiconductor chip 220 may be a logic semiconductor chip, a system on chip, and the like. The second semiconductor chip 220 may be connected to the second chip pad 112. A chip terminal may be disposed on a surface of the second semiconductor chip 220 facing the substrate 100, and the chip terminal may be connected to the second chip pad 112. The chip terminal may be a solder bump, a solder ball, or the like.

The electronic devices 310 and 320 are disposed on at least one of the first and second surfaces of the substrate 100. The electronic devices 310 and 320 may be passive devices. The electronic devices 310 and 320 may be capacitors, inductors, resistors, or the like. The electronic devices 310 and 320 may include a first electronic device 310 and a second electronic device 320.

The first electronic device 310 may be disposed on the first surface of the substrate 100. The first electronic device 310 may be understood as the upper electronic device 310. The first electronic device 310 may be connected to the first device pad 121.

The second electronic device 320 may be disposed on the second surface of the substrate 100. The second electronic device 320 may be understood as the lower electronic device 320. The second electronic device 320 may be connected to the second device pad 122.

The molding layers 410 and 420 function to protect the semiconductor chips 210 and 220 and the electronic devices 310 and 320 from external impact and heat. The molding layers 410 and 420 may include an insulating polymer material such as an epoxy molding compound (EMC). The molding layers 410 and 420 may include a thermosetting resin such as an epoxy resin, a thermoplastic resin such as a polyimide, or a resin including a reinforcing material such as a filler therein. For example, the molding layers 410 and 420 may include an Ajinomoto build-up film (ABF), an FR-4, and a Bismaleimide Triazine (BT) resin.

The molding layers 410 and 420 include a first molding layer 410 and a second molding layer 420.

The first molding layer 410 may be disposed on the first surface of the substrate 100. The first molding layer 410 may be disposed to surround the outside of the first semiconductor chip 210. In addition, the first molding layer 410 may be disposed to surround the outside of the first electronic device 310. The first molding layer 410 may be understood as the upper molding layer 410.

The second molding layer 420 may be disposed on the second surface of the substrate 100. The second molding layer 420 may be disposed to surround the outside of the second electronic device 320. In addition, the second molding layer 420 may be disposed to surround at least a portion of the outside of the second semiconductor chip 220. The second molding layer 420 may be understood as the lower molding layer 420.

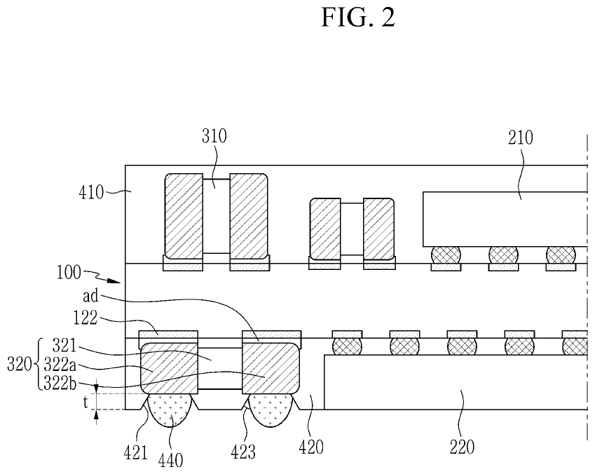

FIG. 2 illustrates an enlarged view of a portion of the semiconductor package of FIG. 1.

Referring to FIG. 2, the second electronic device 320 may have a first surface and a second surface disposed to face in opposite directions. The first surface of the second electronic device 320 may be disposed to face the second surface of the substrate 100. The second surface of the second electronic device 320 may be disposed in the opposite direction of the substrate 100.

The second electronic device 320 includes a body 321 and external electrodes 322a and 322b.

An outer surface of the body 321 may be provided as an insulator. An internal electrode, a coil, or a conductive layer made of a conductive material may be disposed inside the body 321.

The external electrodes 322a and 322b are disposed on the outer surface of the body 321. The external electrodes 322a and 322b may be made of a conductive material. The external electrodes 322a and 322b may be made of a metallic material. The external electrodes 322a and 322b may be connected to the second device pad 122. The external electrodes 322a and 322b may be connected to the second device pad 122 through an adhesive material ad. The adhesive material ad may be a solder or the like.

The external electrodes 322a and 322b may include a first external electrode 322a and a second external electrode 322b. The first external electrode 322a and the second external electrode 322b may be disposed to face each other with the body 321 therebetween. The first external electrode 322a may be disposed across the first surface and the second surface of the second electronic device 320. The second external electrode 322b may be disposed across the first surface and the second surface of the second electronic device 320.

The second molding layer 420 may have a predetermined thickness t in the direction opposite to the substrate 100 between an outer surface of the second molding layer 420 and the second surface of the second electronic device 320. The thickness t of the second molding layer 420 facing the opposite direction of the substrate 100 on the second surface of the second electronic device 320 may be 10 μm or more and 500 μm or less. In an alternative embodiment, the thickness t of the second molding layer 420 facing the opposite direction of the substrate 100 on the second surface of the second electronic device 320 may be 90 μm or more and 110 μm or less.

The thickness t of the second molding layer 420 facing the opposite direction of the substrate 100 on the second surface of the second electronic device 320 may be measured from the second surface of the external electrodes 322a and 322b toward an outer surface of the second molding layer 420 in the opposite direction of the substrate 100. In addition, the thickness t of the second molding layer 420 facing the opposite direction of the substrate 100 on the second surface of the second electronic device 320 may be measured from the second surface of the body 321 toward an outer surface of the second molding layer 420 in the opposite direction of the substrate 100.

The second molding layer 420 may have an open hole 421 that allows at least a portion of the second electronic device 320 to be exposed to the outside. The open hole 421 may be formed in an area in which the external electrodes 322a and 322b of the second electronic device 320 may be disposed in the direction in which the first and second surfaces of the substrate 100 are spaced apart from each other (that is, the vertical direction). The open hole 421 may be formed in an area in which the first external electrode 322a may be disposed and an area in which the second external electrode 322b may be disposed (i.e., the position of the open hole 421 may align with, or correspond to, the position of, one or more of the external electrodes 322a and 322b). Accordingly, the second surfaces of the external electrodes 322a and 322b of the second electronic device 320 may be exposed in the opposite direction of the substrate 100 through the open hole 421. An area of a region (that is, an inner end portion) of the open hole 421 in which the external electrodes 322a and 322b of the second electronic device 320 are disposed may be smaller than an area of a region (that is, an outer end portion) disposed in the opposite direction of the external electrodes 322a and 322b of the second electronic device 320. For example, the area of the open hole 421 may increase as it goes downward.

A connection terminal 440 may be disposed in the inner area of the open hole 421. The connection terminal 440 may be connected to the external electrodes 322a and 322b of the second electronic device 320. The connection terminal 440 allows the semiconductor package 10 to be connected to the outside. The connection terminal 440 may be connected to the first external electrode 322a and the second external electrode 322b, respectively. The connection terminal 440 may be a solder ball or the like. As an example, the connection terminal 440 may be connected to the external electrodes 322a and 322b by being directly attached to the second surfaces of the external electrodes 322a and 322b. At least a portion of the outer surface of the connection terminal 440 may be spaced apart from the inner surface of the open hole 421, so that a gap 423 may be formed between the inner surface of the open hole 421 and the outer surface of the connection terminal 440. The inner surface of the open hole 421 may be disposed so that a material of the second molding layer 420 is exposed.

According to an embodiment of the present disclosure, the semiconductor package 10 may be connected to the outside through the connection terminal 440 connected to the second electronic device 320. Accordingly, the pad for connecting the substrate 100 to the outside may be omitted. That is, the substrate 100 may be manufactured smaller by omitting the area occupied by the pad for connection to the outside, and the semiconductor package 10 may be made smaller.

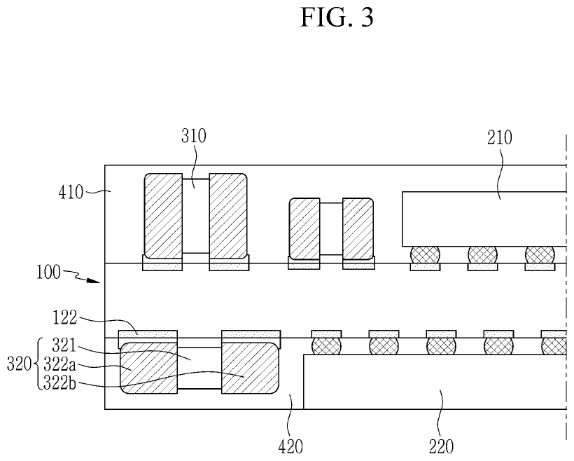

FIG. 3 to FIG. 5 illustrate a process in which a connection terminal is connected to an external electrode of a second electronic device.

Referring to FIG. 3, the semiconductor package 10 to which the connection terminal 440 is connected is provided. The semiconductor package 10 may be provided with the second molding layer 420 formed on the second surface of the substrate 100. In addition, the semiconductor package 10 may have the first molding layer 410 formed on the first surface of the substrate 100.

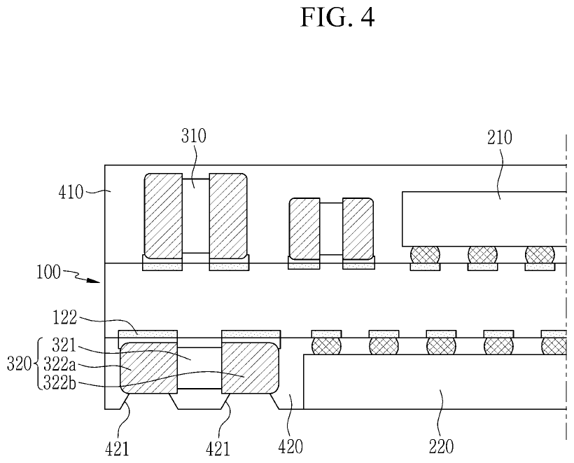

Referring to FIG. 4, the open hole 421 may be formed in the second molding layer 420. The open hole 421 may be formed in the area in which the external electrodes 322a and 322b of the second electronic device 320 are disposed along the direction in which the first and second surfaces of the substrate 100 face each other. Accordingly, the second surfaces of the external electrodes 322a and 322b of the second electronic device 320 may be exposed to the outside. The open hole 421 may be formed using a laser or the like. In addition, after the open hole 421 is formed, a cleaning process may be performed on the area in which the open hole 421 is formed. In the process of forming the open hole 421, the roughness of the area exposed to the open hole 421 of the external electrodes 322a and 322b of the second electronic device 320 may be greater than that of the remaining area.

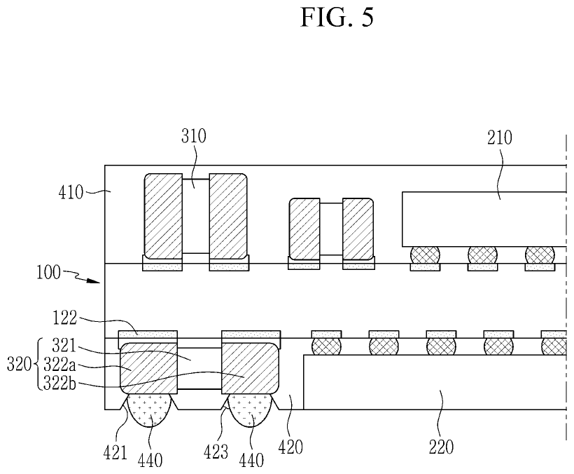

Referring to FIG. 5, the connection terminal 440 may be connected to the second surfaces of the external electrodes 322a and 322b of the second electronic device 320. The connection terminal 440 may be formed by applying a solder or the like to the external electrodes 322a and 322b.

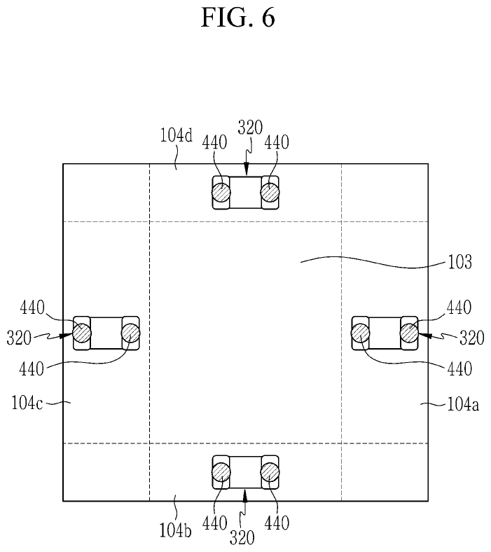

FIG. 6 illustrates a lower surface of a semiconductor package according to a first embodiment.

For better understanding and ease of description, components other than the second electronic device 320 disposed on the second surface of the substrate 100 are not shown.

Referring to FIG. 6, the second surface of the substrate 100 includes a central area 103 and edge areas 104a, 104b, 104c, and 104d.

The central area 103 may be disposed in an inner central area of the second surface of the substrate 100.

The edge areas 104a, 104b, 104c, and 104d may be disposed on an outer circumference of the central area 103. The edge areas 104a, 104b, 104c, and 104d include a first edge area 104a, a second edge area 104b, a third edge area 104c, and a fourth edge area 104d. The first edge area 104a faces the third edge area 104c with the central area therebetween. The second edge area 104b faces the fourth edge area 104d with the central area therebetween.

At least one or more second electronic devices 320 may be disposed in each of the first edge area 104a, the second edge area 104b, the third edge area 104c, and the fourth edge area 104d. Directions in which the external electrodes 322a and 322b are spaced apart from each other in the second electronic device 320 disposed in the first edge area 104a, the second edge area 104b, the third edge area 104c, and the fourth edge area 104d may be the same or different.

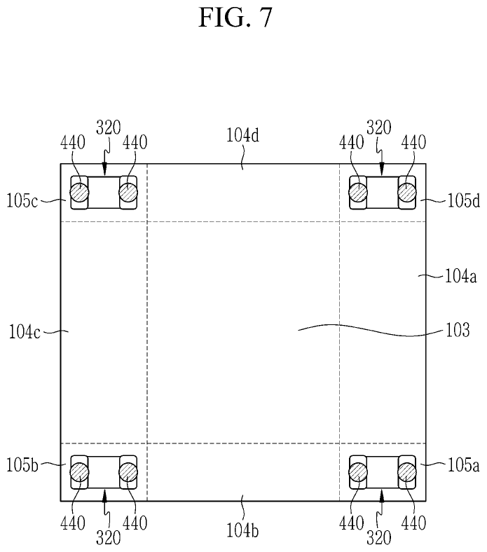

FIG. 7 illustrates a lower surface of a semiconductor package according to a second embodiment.

For better understanding and ease of description, components other than the second electronic device 320 disposed on the second surface of the substrate 100 are not shown.

Referring to FIG. 7, the second surface of the substrate 100 includes a central area 103 and edge areas 104a, 104b, 104c, and 104d.

The central area 103 may be disposed in an inner central area of the second surface of the substrate 100.

The edge areas 104a, 104b, 104c, and 104d may be disposed on an outer circumference of the central area 103. The edge areas 104a, 104b, 104c, and 104d include a first edge area 104a, a second edge area 104b, a third edge area 104c, and a fourth edge area 104d. The first edge area 104a faces the third edge area 104c with the central area therebetween. The second edge area 104b faces the fourth edge area 104d with the central area therebetween.

An area in which the first edge area 104a and the second edge area 104b overlap each other is provided as a first corner area 105a. An area in which the second edge area 104b and the third edge area 104c overlap each other is provided as a second corner area 105b. An area in which the third edge area 104c and the fourth edge area 104d overlap each other is provided as a third corner area 105c. An area in which the fourth edge area 104d and the first edge area 104a overlap each other is provided as a fourth corner area 105d.

At least one or more second electronic devices 320 may be disposed in each of the first corner area 105a, the second corner area 105b, the third corner area 105c, and the fourth corner area 105d. Directions in which the external electrodes 322a and 322b are spaced apart from each other in the second electronic device 320 disposed in the first corner area 105a, the second corner area 105b, the third corner area 105c, and the fourth corner area 105d may be the same or different.

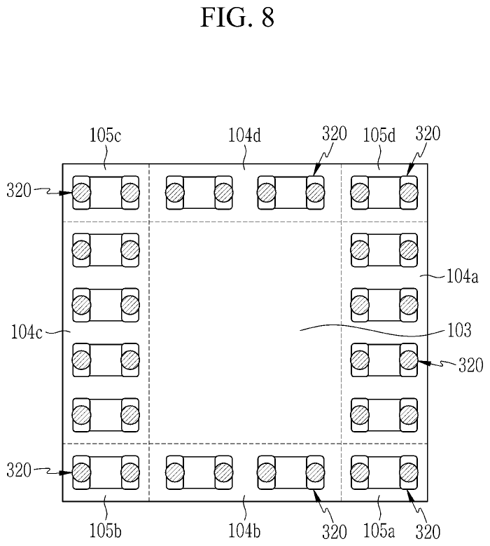

FIG. 8 illustrates a lower surface of a semiconductor package according to a third embodiment.

For better understanding and ease of description, components other than the second electronic device 320 disposed on the second surface of the substrate 100 are not shown.

Referring to FIG. 8, the second surface of the substrate 100 includes a central area 103 and edge areas 104a, 104b, 104c, and 104d.

The central area 103 may be disposed in an inner central area of the second surface of the substrate 100.

The edge areas 104a, 104b, 104c, and 104d may be disposed on an outer circumference of the central area 103. The edge areas 104a, 104b, 104c, and 104d include a first edge area 104a, a second edge area 104b, a third edge area 104c, and a fourth edge area 104d. The first edge area 104a faces the third edge area 104c with the central area therebetween. The second edge area 104b faces the fourth edge area 104d with the central area therebetween.

An area in which the first edge area 104a and the second edge area 104b overlap each other is provided as a first corner area 105a. An area in which the second edge area 104b and the third edge area 104c overlap each other is provided as a second corner area 105b. An area in which the third edge area 104c and the fourth edge area 104d overlap each other is provided as a third corner area 105c. An area in which the fourth edge area 104d and the first edge area 104a overlap each other is provided as a fourth corner area 105d.

At least one or more second electronic devices 320 may be disposed in each of the first corner area 105a, the second corner area 105b, the third corner area 105c, and the fourth corner area 105d. Directions in which the external electrodes 322a and 322b are spaced apart from each other in the second electronic device 320 disposed in the first corner area 105a, the second corner area 105b, the third corner area 105c, and the fourth corner area 105d may be the same or different.

At least one second electronic device 320 may be disposed in a section between the fourth corner area 105d and the first corner area 105a in the first edge area 104a. A plurality of second electronic devices 320 may be disposed in a section between the fourth corner area 105d and the first corner area 105a in the first edge area 104a.

At least one second electronic device 320 may be disposed in a section between the first corner area 105a and the second corner area 105b in the second edge area 104b. A plurality of second electronic devices 320 may be disposed in a section between the first corner area 105a and the second corner area 105b in the second edge area 104b.

At least one second electronic device 320 may be disposed in a section between the second corner area 105b and the third corner area 105c in the third edge area 104c. A plurality of second electronic devices 320 may be disposed in a section between the second corner area 105b and the third corner area 105c in the third edge area 104c.

At least one second electronic device 320 may be disposed in a section between the third corner area 105c and the fourth corner area 105d in the fourth edge area 104d. A plurality of second electronic devices 320 may be disposed in a section between the third corner area 105c and the fourth corner area 105d in the fourth edge area 104d.

Directions in which the external electrodes 322a and 322b are spaced apart from each other in the second electronic device 320 disposed in the first edge area 104a, the second edge area 104b, the third edge area 104c, and the fourth edge area 104d may be the same or different.

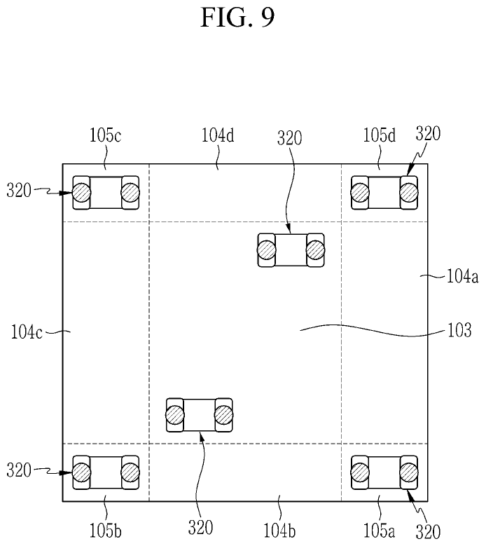

FIG. 9 illustrates a lower surface of a semiconductor package according to a fourth embodiment.

For better understanding and ease of description, components other than the second electronic device 320 disposed on the second surface of the substrate 100 are not shown.

Referring to FIG. 9, the second surface of the substrate 100 includes a central area 103 and edge areas 104a, 104b, 104c, and 104d.

The central area 103 may be disposed in an inner central area of the second surface of the substrate 100.

The edge areas 104a, 104b, 104c, and 104d may be disposed on an outer circumference of the central area 103. The edge areas 104a, 104b, 104c, and 104d include a first edge area 104a, a second edge area 104b, a third edge area 104c, and a fourth edge area 104d. The first edge area 104a faces the third edge area 104c with the central area therebetween. The second edge area 104b faces the fourth edge area 104d with the central area therebetween.

An area in which the first edge area 104a and the second edge area 104b overlap each other is provided as a first corner area 105a. An area in which the second edge area 104b and the third edge area 104c overlap each other is provided as a second corner area 105b. An area in which the third edge area 104c and the fourth edge area 104d overlap each other is provided as a third corner area 105c. An area in which the fourth edge area 104d and the first edge area 104a overlap each other is provided as a fourth corner area 105d.

At least one or more second electronic devices 320 may be disposed in the central area 103.

In addition, the second electronic device 320 may be disposed in the edge areas 104a, 104b, 104c, and 104d. The form in which the second electronic device 320 is disposed in the edge areas 104a, 104b, 104c, and 104d may be the same as one of the embodiments described above with reference to FIG. 6 to FIG. 8.

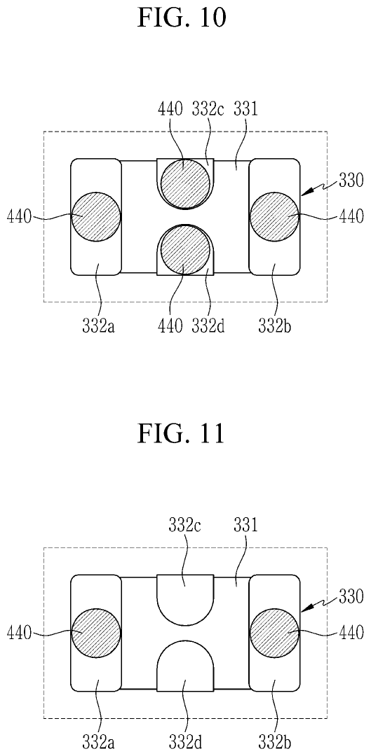

FIG. 10 and FIG. 11 illustrate a state in which a connection terminal is connected to a second electronic device according to the second embodiment.

Referring to FIG. 10 and FIG. 11, a second electronic device 330 has a first surface and a second surface disposed to face in opposite directions. The first surface of the second electronic device 330 may be disposed to face the second surface of the substrate 100. The second surface of the second electronic device 330 may be disposed in the opposite direction of the substrate 100.

The second electronic device 330 includes a body 331 and external electrodes 332a, 332b, 332c, and 332d.

An outer surface of the body 331 may be provided as an insulator. An internal electrode, a coil, or a conductive layer made of a conductive material may be disposed inside the body 331.

The external electrodes 332a, 332b, 332c, and 332d may be disposed on an outer surface of the body 331. The external electrodes 332a, 332b, 332c, and 332d may be made of a conductive material. The external electrodes 332a, 332b, 332c, and 332d may be made of a metallic material. The external electrodes 332a, 332b, 332c, and 332d may be connected to the second device pad 122.

The external electrodes 332a, 332b, 332c, and 332d include a first external electrode 332a, a second external electrode 332b, a third external electrode 332c, and a fourth external electrode 332d. As an example, the second electronic device 330 may be a three-terminal capacitor.

The first external electrode 332a, the second external electrode 332b, the third external electrode 332c, and the fourth external electrode 332d may be disposed on the outer surface of the body 331. The first external electrode 332a, the second external electrode 332b, the third external electrode 332c, and the fourth external electrode 332d may be made of a conductive material. The first external electrode 332a, the second external electrode 332b, the third external electrode 332c, and the fourth external electrode 332d may be made of a metallic material.

The first external electrode 332a and the second external electrode 332b may be disposed to face each other with the body 331 therebetween. The first external electrode 332a and the second external electrode 332b may be disposed across the first surface and the second surface of the second electronic device 330.

The third external electrode 332c and the fourth external electrode 332d may be disposed to face each other with the body 331 therebetween. A direction in which the first external electrode 332a and the second external electrode 332b face each other and a direction in which the third external electrode 332c and fourth external electrode 332d face each other may cross each other. A distance between the first external electrode 332a and the second external electrode 332b may be greater than a distance between the third external electrode 332c and the fourth external electrode 332d.

A direction in which the first external electrode and the second external electrode 332b face each other and a direction in which the third external electrode 332c and the fourth external electrode 332d face each other may be disposed on a plane that crosses a direction in which the first and second surfaces of the second electronic device 330 face each other. The third external electrode 332c and the fourth external electrode 332d may be disposed across the first surface and the second surface of the second electronic device 330.

In the second molding layer 420, an open hole 421 may be formed in a direction in which the first and second surfaces of the substrate 100 are spaced apart from each other in the area in which the external electrodes 332a, 332b, 332c, and 332d of the second electronic device 330 are disposed. At least two open holes 421 may be formed in the area in which one second electronic device 330 is disposed. The open hole 421 may be formed in at least two areas of an area in which the first external electrode 332a is disposed, an area in which the second external electrode 332b is disposed, an area in which the third external electrode 332c is disposed, and an area in which the fourth external electrode 332d is disposed. In addition, the connection terminal 440 may be disposed in the open hole 421 to be connected to one of the external electrodes 332a, 332b, 332c, and 332d.

For example, the open hole 421 may be respectively formed in an area in which the first external electrode 332a is disposed, an area in which the second external electrode 332b is disposed, an area in which the third external electrode 332c is disposed, and an area in which the fourth external electrode 332d is disposed.

A connection terminal 440 may be connected to the external electrodes 332a, 332b, 332c, and 332d of the second electronic device 330. The connection terminal 440 allows the semiconductor package 10 to be connected to the outside. The connection terminal 440 may be connected to the first external electrode 332a, the second external electrode 332b, the third external electrode 332c, and the fourth external electrode 332d, respectively.

In addition, the open hole 421 may be formed in an area in which the first external electrode 332a is disposed and an area in which the second external electrode 332b is disposed. In the open hole 421, an area in which the third external electrode 332c is disposed and an area in which the fourth external electrode 332d is disposed may be omitted. In addition, the connection terminal 440 may be connected to the first external electrode 332a and the second external electrode 332b, respectively.

At least one or more second electronic devices 330 according to the second embodiment may be included in the semiconductor package 10 described above with reference to FIG. 1 to FIG. 9.

That is, the semiconductor package 10 may include a second electronic device 320 including two external electrodes 322a and 322b and a second electronic device 330 including four external electrodes 332a, 332b, 332c, and 332d.

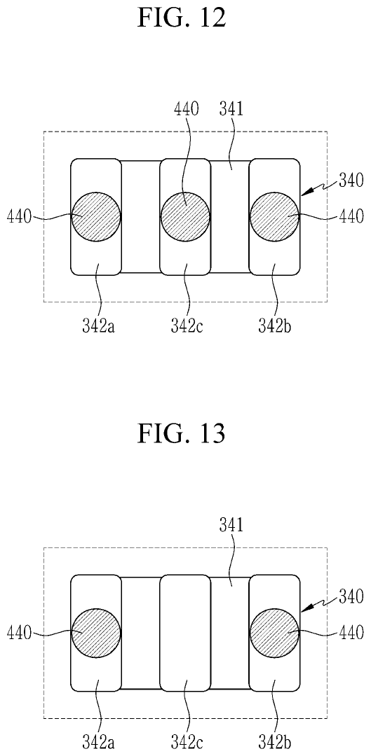

FIG. 12 and FIG. 13 illustrate a state in which a connection terminal is connected to a second electronic device according to the third embodiment.

Referring to FIG. 12 and FIG. 13, a second electronic device 340 has a first surface and a second surface disposed to face in opposite directions. The first surface of the second electronic device 340 may be disposed to face the second surface of the substrate 100. The second surface of the second electronic device 340 may be disposed in the opposite direction of the substrate 100.

The second electronic device 340 includes a body 341 and external electrodes 342a, 342b, and 342c.

An outer surface of the body 341 may be provided as an insulator. An internal electrode, a coil, or a conductive layer made of a conductive material may be disposed inside the body 341.

The external electrodes 342a, 342b, and 342c may be disposed on an outer surface of the body 341. The external electrodes 342a, 342b, and 342c may be made of a conductive material. The external electrodes 342a, 342b, and 342c may be made of a metallic material. The external electrodes 342a, 342b, and 342c may be connected to the second device pad 122.

The external electrodes 342a, 342b, and 342c include a first external electrode 342a, a second external electrode 342b, and a third external electrode 342c.

The first external electrode 342a, the second external electrode 342b, and the third external electrode 342c may be disposed on the outer surface of the body 341. The first external electrode 342a and the second external electrode 342b may be disposed to face each other with the body 341 therebetween. The third external electrode 342c may be disposed between the first external electrode 342a and the second external electrode 342b. The first external electrode 342a and the second external electrode 342b may be disposed across the first surface and the second surface of the second electronic device 340. The third external electrode 342c may be disposed across the first surface and the second surface of the second electronic device 340.

In the second molding layer 420, an open hole 421 may be formed in a direction in which the first and second surfaces of the substrate 100 are spaced apart from each other in the area in which the external electrodes 342a, 342b, and 342c of the second electronic device 340 are disposed. At least two open holes 421 may be formed in the area in which one second electronic device 340 is disposed. The open hole 421 may be formed in at least two areas of an area in which the first external electrode 342a is disposed, an area in which the second external electrode 342b is disposed, and an area in which the third external electrode 342c is disposed. In addition, the connection terminal 440 may be disposed in the open hole 421 to be connected to one of the external electrodes 342a, 342b, and 342c.

As an example, the open hole 421 may be formed in an area in which the first external electrode 342a is disposed, an area in which the second external electrode 342b is disposed, and an area in which the third external electrode 342c is disposed, respectively.

A connection terminal 440 may be connected to the external electrodes 342a, 342b, and 342c of the second electronic device 340. The connection terminal 440 allows the semiconductor package 10 to be connected to the outside. The connection terminal 440 may be connected to the first external electrode 342a, the second external electrode 342b, and the third external electrode 342c, respectively.

In addition, the open hole 421 may be formed in an area in which the first external electrode 342a is disposed and an area in which the second external electrode 342b is disposed. An area of the open hole 421 in which the third external electrode 342c is disposed may be omitted. In addition, the connection terminal 440 may be connected to the first external electrode 342a and the second external electrode 342b, respectively.

At least one or more second electronic devices 340 according to the third embodiment may be included in the semiconductor package 10 described above with reference to FIG. 1 to FIG. 9.

That is, the semiconductor package 10 may include a second electronic device 320 including two external electrodes 322a and 322b and a second electronic device 340 including three external electrodes 342a, 342b, and 342c.

In addition, the semiconductor package 10 may include a second electronic device 320 including two external electrodes 322a and 322b; a second electronic device 330 including four external electrodes 332a, 332b, 332c, and 332d; and a second electronic device 340 including three external electrodes 342a, 342b, and 342c.

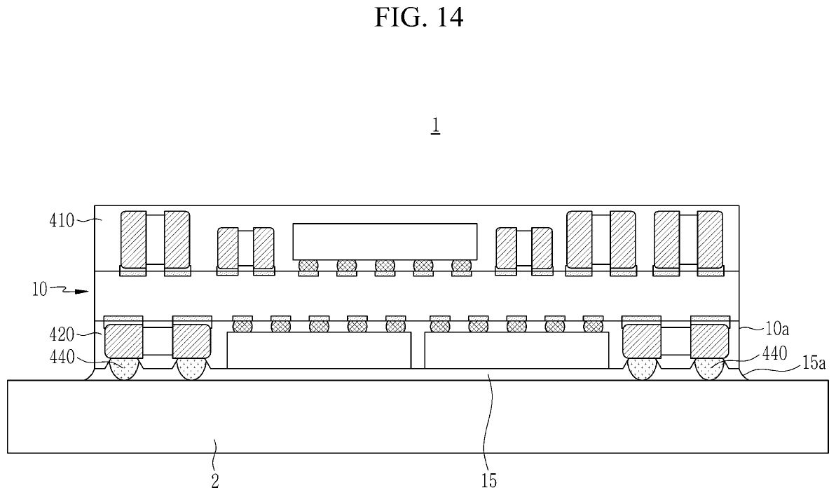

FIG. 14 illustrates a semiconductor assembly including a semiconductor package according to an embodiment.

Referring to FIG. 14, a semiconductor assembly 1 includes main substrate 2 and the semiconductor package 10.

The main substrate 2 may have a first surface and a second surface disposed to face in opposite directions.

The semiconductor package 10 may be mounted on the main substrate 2. The semiconductor package 10 may have a first surface and a second surface disposed to face in opposite directions. The first molding layer 410 may be disposed on the first surface. The second molding layer 420 may be disposed on the second surface. The outer surface may be disposed between the first and second surfaces. The first surface of the semiconductor package 10 may be an upper surface, and the second surface thereof may be a lower surface.

The semiconductor package 10 may be mounted on the main substrate 2 such that the second molding layer 420 faces the second surface of the main substrate 2. The semiconductor package 10 may be connected to the main substrate 2 through the connection terminal 440. An underfill molding layer 15a may be disposed between the semiconductor package 10 and the main substrate 2. The underfill molding layer 15a may be formed by mounting the semiconductor package 10 on the main substrate 2 and then filling a molding material between the main substrate 2 and the semiconductor package 10. The underfill molding layer 15a may be filled in the gap 423 formed between the inner surface of the open hole 421 and the side surface of the connection terminal 440. Accordingly, a boundary between the underfill molding layer 15a and the second molding layer 420 may be disposed on at least a portion of the inner surface of the open hole 421 before the underfill molding layer 15a is formed. The boundary between the underfill molding layer 15a and the second molding layer 420 may be confirmed through an SEM photograph or the like. The underfill molding layer 15a may be formed to be in contact with an outer area other than a portion in contact with the main substrate 2 in the connection terminal 440.

The outer surface of the semiconductor package 10 and the externally exposed surface of the underfill molding layer 15a may have different shapes. An area 10a adjacent to the second surface on the outer surface of the semiconductor package 10 may be linear in the direction (that is, the vertical direction) in which the first and second surfaces of the semiconductor package 10 are spaced apart from each other. The underfill molding layer 15a may have a shape that spreads outward from the semiconductor package 10 toward the main substrate 2.

While the embodiment of the present disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a substrate comprising a first surface and a second surface, wherein the second surface is disposed in an opposite direction to the first surface;
a semiconductor chip on one of the first surface or the second surface;
a first electronic device on the second surface;
a first molding layer on the first surface; and
a second molding layer on the second surface,
wherein the second molding layer comprises an first open hole that exposes at least a portion of the first electronic device to an outside, and
wherein a material of the second molding layer is located on at least a portion of an inner surface of the first open hole.

2. The semiconductor package of claim 1, wherein the first open hole is disposed in an area of the second molding layer corresponding to a position of an external electrode of the first electronic device.

3. The semiconductor package of claim 2, wherein a connection terminal is disposed in an inner area of the first open hole.

4. The semiconductor package of claim 3, wherein the connection terminal is connected to the external electrode.

5. The semiconductor package of claim 3, wherein a gap is formed between the inner surface of the first open hole and an outer surface of the connection terminal.

6. The semiconductor package of claim 1,
wherein the second surface comprises:
a central area; and
a first edge area, a second edge area, a third edge area, and a fourth edge area,
wherein the first edge area, the second edge area, the third edge area, and the fourth edge area form an outer circumference of the central area,
wherein the first edge area is on a side of the substrate opposite from the third edge area, with the central area therebetween, and
wherein the second edge area is on a side of the substrate opposite from the fourth edge area, with the central area therebetween.

7. The semiconductor package of claim 6, wherein one or more electronic devices, including the first electronic device, are disposed in the first edge area, the second edge area, the third edge area, and the fourth edge area.

8. The semiconductor package of claim 6, wherein one or more electronic devices, including the first electronic device, are disposed in areas of the second surface in which the first edge area, the second edge area, the third edge area and the fourth edge area overlap each other.

9. The semiconductor package of claim 6, wherein one or more electronic devices, including the first electronic device, are disposed in the central area.

10. The semiconductor package of claim 1,
wherein the first electronic device comprises a first device surface facing the second surface of the substrate, and a second device surface facing in a direction opposite from the first device surface and away from the second surface of the substrate, and
wherein a portion of the second molding layer between the second device surface and a surface of the second molding layer facing away from the second surface of the substrate has a thickness greater than or equal to 10 μm and less than or equal to 500 μm.

11. The semiconductor package of claim 1, wherein
wherein the first electronic device comprises a first device surface facing the second surface of the substrate, and a second device surface facing in a direction opposite from the first device surface and away from the second surface of the substrate, and
wherein a portion of the second molding layer between the second device surface and a surface of the second molding layer facing away from the second surface of the substrate has a thickness greater than or equal to 90 μm and less than or equal to 110 μm.

12. The semiconductor package of claim 1,
wherein the first electronic device comprises:
a body;
a first external electrode; and
a second external electrode, and
wherein the first external electrode and the second external electrode are disposed on an outer surface of the body.

13. The semiconductor package of claim 1,
wherein the first electronic device comprises:
a body;
a first external electrode;
a second external electrode;
a third external electrode; and
a fourth external electrode,
wherein the first external electrode, the second external electrode, the third external electrode, and the fourth external electrode are disposed on an outer surface of the body,
wherein the second molding layer further comprises a second open hole that exposes at least a portion of the first electronic device to the outside, and
wherein the first open hole and the second open hole are formed in an area of the second molding layer corresponding to a position of the first electronic device.

14. The semiconductor package of claim 1,
wherein the first electronic device comprises:
a body;
a first external electrode;
a second external electrode; and
a third external electrode,
wherein the first external electrode, the second external electrode, and the third external electrode are disposed on an outer surface of the body, wherein the second molding layer further comprises a second open hole that exposes at least a portion of the first electronic device to the outside, and
wherein the first open hole and the second open hole are formed in an area of the second molding layer corresponding to a position of the first electronic device.

15. A semiconductor package comprising:
a substrate comprising a first surface and a second surface, wherein the second surface is disposed in an opposite direction to the first surface;
a first semiconductor chip on the first surface;
a second semiconductor chip on the second surface;
a first electronic device on the first surface;
a second electronic device on the second surface;
a first molding layer on the first surface; and
a second molding layer on the second surface,
wherein the second molding layer comprises a first open hole that exposes at least a portion of the second electronic device to an outside,
wherein a material of the second molding layer is located on at least a portion of an inner surface of the first open hole, and
wherein a connection terminal connected to an external electrode of the second electronic device is disposed inside the first open hole.

16. The semiconductor package of claim 15, wherein the second electronic device comprises a first device surface facing the second surface of the substrate, and a second device surface facing in a direction opposite from the first device surface and away from the second surface of the substrate, and
wherein a portion of the second molding layer between the second device surface and a surface of the second molding layer facing away from the second surface of the substrate has a thickness greater than or equal to 90 μm and less than or equal to 110 μm.

17. The semiconductor package of claim 15,
wherein the external electrode of the second electronic device comprises a first external electrode, a second external electrode, a third external electrode, and a fourth external electrode,
wherein the second molding layer further comprises a second open hole that exposes at least a portion of the second electronic device to the outside, and
wherein the first open hole and the second open hole are formed in an area of the second molding layer corresponding to a position of the second electronic device.

18. The semiconductor package of claim 15,
wherein the external electrode of the second electronic device comprises a first external electrode, a second external electrode, and a third external electrode, wherein the second molding layer further comprises a second open hole that exposes at least a portion of the second electronic device to the outside, and
wherein the first open hole and the second open hole are formed in an area of the second molding layer corresponding to a position of the second electronic device.

19. A semiconductor assembly comprising:
a main substrate; and
a semiconductor package mounted on the main substrate,
wherein the semiconductor package comprises:
a substrate comprising a first surface and a second surface, wherein the second surface is disposed in an opposite direction to the first surface;
a first semiconductor chip on the first surface;
a second semiconductor chip on the second surface;
a first electronic device on the first surface;
a second electronic device on the second surface;
a first molding layer on the first surface; and
a second molding layer on the second surface,
wherein the second molding layer comprises an open hole that exposes at least a portion of the second electronic device to an outside,
wherein a material of the second molding layer is located on at least a portion of an inner surface of the open hole, and
wherein a connection terminal connected to an external electrode of the second electronic device is disposed inside the open hole.

20. The semiconductor assembly of claim 19, further comprising an underfill molding layer disposed between the semiconductor package and the main substrate.
